(19) United States
(12) Patent Application Publication
(10) Pub. No.: US 2004/0210710 A1
(43) Pub. Date: Oct. 21, 2004

(54) Method for adaptive control of DRAM refresh interval

(76) Inventor: Yuan-Mou Su, Tainan County (TW)

Correspondence Address: BIRCH STEWART KOLASCH & BIRCH, PO BOX 747, FALLS CHURCH, VA, 22040-0747, US

(21) Appl. No.: 10/763,250

(22) Filed: Jan. 26, 2004

(30) Foreign Application Priority Data
Apr. 17, 2003 (TW) 092108886

(51) Int. Cl. G06F 12/00; G11C 7/00

(52) U.S. Cl. 711/106; 365/222

(57) ABSTRACT

The present invention relates to a method for finding the appropriate refresh interval applied for DRAM of the present invent, comprising, detecting startup, providing a clock pulse as a refresh interval, DRAM self-testing of a plurality of memory cells with the provided refresh interval, modifying the refresh interval and repeating the above steps to find the longest refresh interval as determined by the DRAM self-testing procedure, and using the determined appropriate refresh interval to refresh the DRAM. Therefore, the appropriate refresh interval, found form the method of the present invention, could be adjusted with the DRAM chip for saving the power with refresh.

### BACKGROUND OF THE INVENTION

1. Field of the Invention

The present invention relates in general to a technology for controlling the refresh interval of dynamic random access memory (DRAM), and more particularly to a method and apparatus for DRAM self-testing at startup.

2. Description of the Related Art

DRAM, the most commonly used solid state access memory chip provides many advantages, such as high density, low cost, and high operating speed among others. DRAM stores memory data by electric charge, however, and the electric charge gradually lost over time by the reverse bias voltage leakage current of the PN junction of the NMOS transistor in the DRAM memory cell. Hence, the DRAM chip must be continuously updated, even in stand-by mode, to prevent data loss over time. The process of updating DRAM memory data is known as a refresh and the time elapsed between refresh processes is known as the refresh interval. A high frequency, or shorter, refresh interval is inefficient as it consumes excessive power.

Power management in primarily battery powered devices such as PDAs and cell phones, is particularly important as power must be consumed as conservatively as possible to prolong battery life.

Therefore, reducing power consumption has become the most important issue in DRAM research, especially regarding the refresh interval.

### SUMMARY OF THE INVENTION

Accordingly, an object of the present invention is to provide an appropriate refresh interval for reducing the power consumption.

The present invention provides a method for determining an appropriate refresh interval comprising, detecting startup, providing a clock pulse as a refresh interval, DRAM self-testing of a plurality of memory cells with the provided refresh interval, modifying the refresh interval and repeating the above steps to find the longest refresh interval as determined by the DRAM self-testing procedure, and using the determined appropriate refresh interval to refresh the DRAM.

Additionally, to prevent data loss and reduce power consumption in stand-by mode, the refresh interval must frequent enough to sufficiently refresh the DRAM, while still offering reduced power consumption.

Accordingly, the DRAM self-test at startup of the present invention enables use of a refresh interval appropriate for maintaining data and reducing power consumption.

A detailed description is given in the following with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a flow chart diagram of the present invention;

FIG. 2 is a circuit diagram of a ring-type oscillator of the present invention;

FIG. 3 is a circuit diagram of a phase inverter of FIG. 2; and

FIG. 4 is a schematic diagram of the control voltage circuit shown in FIG. 3;

### DETAILED DESCRIPTION OF THE INVENTION

The object of the present invention is to determine an appropriate refresh interval by DRAM self-testing at startup.

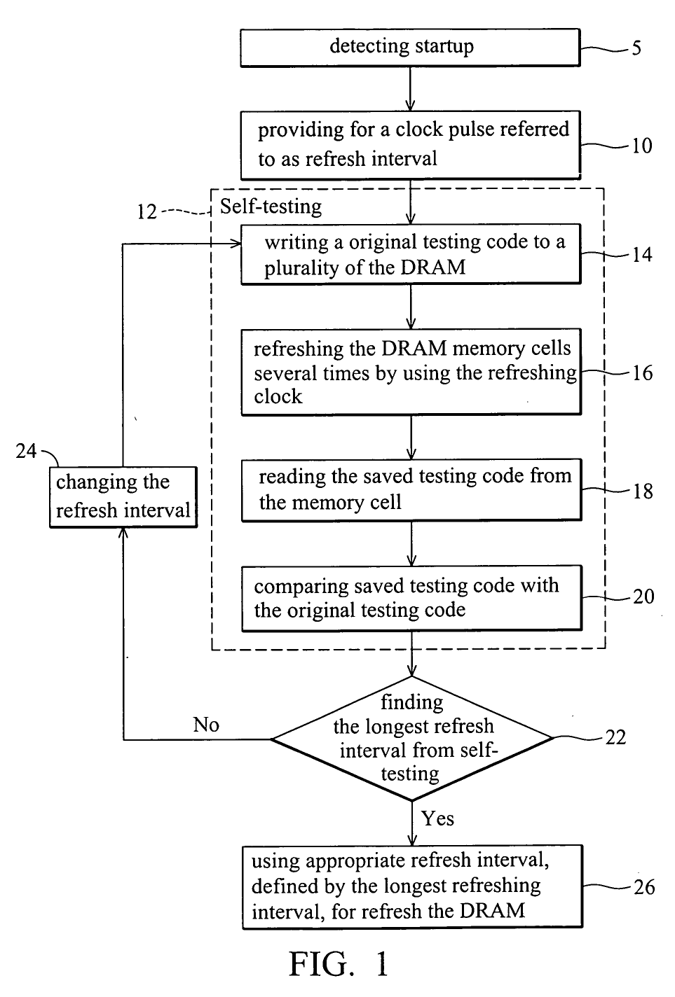

FIG. 1 is flowchart diagram of the present invention. When startup 5 is detected a refresh interval 10 is provided for DRAM for self-testing. The self-testing procedure continues for a plurality of memory cells 12 until the longest refresh interval 22 is determined. Finally, the DRAM 26 is refreshed using the longest refresh interval as determined by self-testing.

The object of the self-testing procedure 12 is to prevent data loss by using the appropriate refresh interval 10. Thus, during the self-testing procedure 12, an original test code is first written to a plurality of the memory cells 14. The memory cells are then refreshed using the provided refresh interval. The saved test code is then read from the memory cell 18, and finally, the saved test code is compared with the original test code 20. An equal result obtained in step 20 indicates that the present refresh interval is sufficient to prevent data loss. An unequal result obtained in step 20 indicates that the present refresh interval is too long to sufficiently prevent data loss.

Additionally, if after the first loop of the self-testing procedure to find the longest refresh interval, the result of step 20 is equal the current refresh interval is increased and the procedure returns to step 12 until the result of step 20 is unequal.

In contrast, if after the first loop of the self-testing procedure to find the longest refresh interval, the result of step 20 is unequal the current refresh interval is decreased and the procedure returns to step 12 until the result of step 20 is equal.

Hence, a refresh interval capable of both preventing data loss and reducing power consumption can be determined by the self-testing method 10 described in the following.

The refresh interval may be determined, however, from testing only a sample of the total number of memory cells, which still leaves a measure of uncertainty regarding effectiveness. Thus, it is necessary to determine a refresh interval capable of attaining the goals of data retention and reduced power consumption.

Thus, the appropriate refresh interval is determined as the longest refresh interval plus a specific variable, to prevent refresh failure in other memory cells while maintaining improved performance.

Finally, by using the appropriate refresh interval refresh DRAM during normal operation prevents data loss and reduced power consumed by the refresh interval.

The length and the content of the original test code can be designed as a DRAM array structure or be chosen at random.

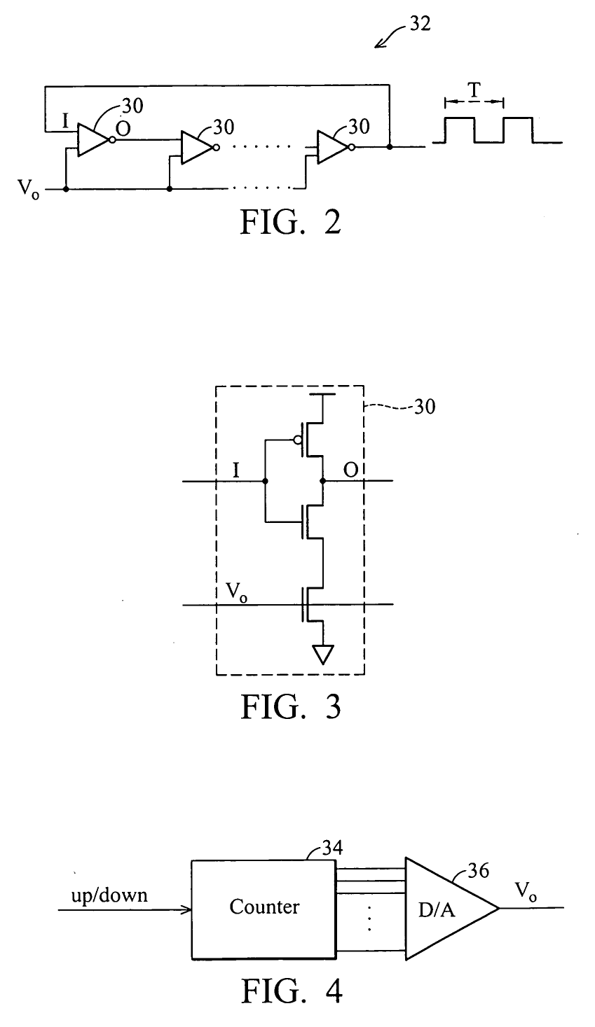

Referring to FIG. 2, a ring-type oscillator 32 of the present invention is shown, wherein the ring-type oscillator 32 comprises an odd number of phase inverter 30 connected in series, and the output port of the final one end is connected to the input port of the first phase inverter 30 to act as a ring-type oscillator 32.

FIG. 3 is a circuit diagram of a phase inverter 30 of FIG. 2, wherein the driving current of the phase inverter 30 is controlled by a potential Vₒ. In FIG. 2, the potential Vₒ controls the discharged current of phase inverter 30 to modify the oscillatory period of the ring-type oscillator 32. For example, discharged current can be increased by elevating the potential Vₒ, thus decreasing oscillatory period T.

FIG. 4 is a schematic diagram of the control voltage circuit shown in FIG. 3, wherein the counter 34 is controlled by an up/down control signal to output a control value. After receiving the control value, a digital-to-analog converter (D/A converter) 36 outputs the potential Vₒ. Thus, as shown in FIG. 1, the up/down control signal value is determined by step 22. For example, to increase the potential Vₒ and reduce the oscillatory period of the ring-type oscillator 32 when the refresh interval is too long to maintain data in the memory cell, the value of counter 34 is increased. Conversely, the value of counter 34 is reduced to increase the oscillatory period until the appropriate refresh interval is determined.

Hence, by using the present values of counter 34, the system can determine the appropriate refresh interval after determining the longest refresh interval.

Therefore, comparatively, the appropriate refresh interval can be determined by the method of the present invention, and ameliorates the disadvantages of the prior art.

While the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation to encompass all such modifications and similar arrangements.

What is claimed is:

1. A method of determining an appropriate refresh interval for a DRAM chip, the method comprising:
detecting device startup;
providing a clock pulse as a refresh interval;
self-testing a plurality of memory cells using the refresh interval;
modifying the refresh interval and repeating the above steps;
determining the longest refresh interval as a result of the self-testing procedure; and
using the appropriate refresh interval, defined by the longest refresh interval, to refresh the DRAM.

2. The method of determining the appropriate refresh interval as claimed in claim 1, wherein the self-testing comprises:
writing an original test code to a plurality of DRAM memory cells;
refresh the DRAM memory cells several times by using the refresh clock;
comparing saved test code with the original test code, to determine the effectiveness of the refresh interval;
if the result of the comparison is equal, the system outputs a self-test success signal; and
if the result of the comparison is unequal, the system outputs a self-test failure signal.

3. The method of finding the appropriate refresh interval as claimed in claim 1, wherein the definition of the most appropriate refresh interval comprises:
the most appropriate refresh interval is the longest refresh interval plus a specific variable.
